(19) United States
(12) Patent Application Publication
(10) Pub. No.: US 2021/0184091 A1
(43) Pub. Date: Jun. 17, 2021

(54) DISPLAY MODULE ADJUSTMENT METHOD OF MOBILE DEVICE AND LIGHT-EMITTING DIODE ARRAY DRIVING SYSTEM

(71) Applicant: SILICON TOUCH TECHNOLOGY INC., Hsinchu (TW)

(72) Inventor: CHI-YUAN CHIN, HSINCHU (TW)

(21) Appl. No.: 17/016,723

(22) Filed: Sep. 10, 2020

(30) Foreign Application Priority Data
Dec. 13, 2019 (TW) 108145685

(51) Int. Cl. H01L 33/62; H01L 27/15; H01L 27/32; G02F 1/1333

(52) U.S. Cl. CPC H01L 33/62; G02F 1/13338; H01L 27/3234; H01L 27/156

(57) ABSTRACT

A light-emitting diode array driving system and a display module adjustment method are provided. The light-emitting diode array driving system includes a driving module, and a light-emitting diode array. The driving module includes a plurality of driving units electrically connected to signal driving lines. The light-emitting diode array includes a plurality of light-emitting diode modules. The plurality of light-emitting diode modules are arranged in a matrix. The light-emitting diode modules arranged in the same row or the light-emitting diode modules arranged in the same column are electrically connected to one of the plurality of signal driving lines. The driving units respectively provide a driving signal to the plurality of signal driving lines. The light-emitting diode modules connected to the same signal driving line respectively extract, based on a sequence, a driving unit signal of the driving signal.

### CROSS-REFERENCE TO RELATED PATENT APPLICATION

This application claims the benefit of priority to Taiwan Patent Application No. 108145685, filed on Dec. 13, 2019. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a display module adjustment method of mobile device and a light-emitting diode array driving system, and more particularly to a low-cost display module adjustment method of the mobile device and a low-cost light-emitting diode array driving system.

### BACKGROUND OF THE DISCLOSURE

If a display screen of an existing mobile device has dark spots or defects, a user needs to bring over the entire mobile device for maintenance. This way, maintenance time is longer and maintenance costs are higher. In addition, the implementation of light-emitting elements of the display screen is also a factor affecting the maintenance cost of the mobile device.

Therefore, providing a low-cost mobile device display module adjustment method and a light-emitting diode array driving system has become an important issue in the industry.

### SUMMARY OF THE DISCLOSURE

In response to the above-referenced technical inadequacies, the present disclosure provides a light-emitting diode array driving system. The light-emitting diode array driving system includes a driving module and a light-emitting diode array. The driving module includes a plurality of driving units. The plurality of driving units are electrically connected to a plurality of signal driving lines. The light-emitting diode array includes a plurality of light-emitting diode modules. The plurality of light-emitting diode modules are arranged in a matrix. The light-emitting diode modules arranged in the same row or the light-emitting diode modules arranged in the same column are electrically connected to one of the signal driving lines. The driving units of the driving module respectively provide a driving signal to the plurality of signal driving lines. The light-emitting diode modules connected to the same signal driving line respectively extract, based on a sequence, at least one driving unit signal of the driving signal to drive the light-emitting diode module.

In one aspect, the present disclosure provides a display module adjustment method of a mobile device. The display module adjustment method of the mobile device includes: capturing a first image information of a display module of the mobile device; transmitting the first image information to a server; providing a display module adjustment scheme to the mobile device based on at least one area to be adjusted of the first image information; adjusting the display module based on the display module adjustment scheme, capturing a second image information, and transmitting the second image information to the sever; and confirming an adjustment result based on the second image information.

Therefore, the display module adjustment method provided in the present disclosure can effectively reduce the time and cost spent on mailing or bringing over the mobile device for maintenance. Furthermore, the light-emitting diode array driving system provided by the present disclosure can simplify the circuit structure and reduce the installation cost and maintenance cost.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a schematic diagram of a display module adjustment method of a first embodiment of the present disclosure.

FIG. 2 is a flow chart of the display module adjustment method of the first embodiment of the present disclosure.

FIG. 3 is a schematic diagram of a light-emitting diode array driving system of a second embodiment of the present disclosure.

FIG. 4 is a schematic diagram of a light-emitting diode module of the second embodiment of the present disclosure.

FIG. 5 is a schematic diagram of driving unit signals of the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

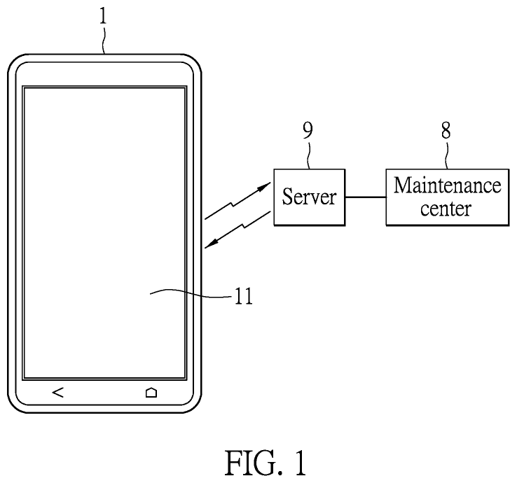

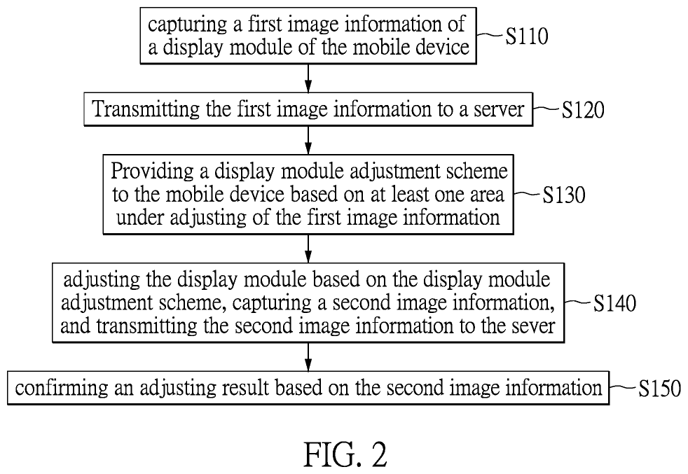

Referring to FIG. 1 and FIG. 2, FIG. 1 is a schematic diagram of a display module adjustment method of a first embodiment of the present disclosure. FIG. 2 is a flow chart of the display module adjustment method of the first embodiment of the present disclosure.

Referring to FIG. 1, a mobile device 1 in this embodiment can capture the image information of a display module 11 of the mobile device 1 and transmit the captured image information to a server 9. In other words, when the display module 11 of the mobile device 1 has dark spots, light leakage, or other defects, a user can capture at least one image information of the display module 11 by a screen capture function of the mobile device 1. The user then transmits at least one captured image information to the server 9 via a network. The server 9 may be a server implemented by a manufacturer of the mobile device 1 or a maintenance service provider.

After the user transmits the image information of the mobile device 1 to the server 9, the server 9 transmits a maintenance message to a maintenance center 8, such that a maintenance personnel can analyze the image information of the mobile device 1 and provide solutions. In this embodiment, the mobile device 1 is a smart phone, a tablet computer or a wearable electronic device, but it is not limited in the present disclosure. After confirming the issue and the adjustment scheme, the maintenance personnel of the maintenance center 8 can provide a display module adjustment scheme to the user through the server 9. The user can adjust the mobile device 1 based on the display module adjustment scheme.

Referring to FIG. 2, the display module adjustment method includes steps as follows:

capturing a first image information of a display module of the mobile device (step S110);

transmitting the first image information to a server (step S120);

providing a display module adjustment scheme to the mobile device based on at least one area to be adjusted of the first image information (step S130);

adjusting the display module based on the display module adjustment scheme, capturing a second image information, and transmitting the second image information to the sever (step S140); and

confirming an adjustment result based on the second image information (step S150).

In step S110, when the display module of the mobile device 1 has dark spots, light leakage, or other defects, the user can capture at least one image information of the display module 11 by a screen capture function of the mobile device 1. The image information is the first image information of the display module 11. In this embodiment, the first image information is a black screen image or a blank screen image. In other embodiments, the manufacturer can provide multiple image capturing modes for users to sequentially capture image information, such that the maintenance personnel of the maintenance center 8 can easily determine or confirm issues of the display module 11. In this embodiment, the display module 11 is a liquid crystal display module, an organic light-emitting diode display module, or a light-emitting diode display module, but it is not limited in the present disclosure.

In step S120, the user transmits the first image information to the server 9 by the mobile device 1. At the same time, the user can also provide information of a model number of the mobile device 1 and operating system specifications to the server 9. The maintenance personnel of the maintenance center 8 can quickly provide an adjustment scheme, according to the information such as the model number of the mobile device 1 and operating system specifications.

In step S130, the maintenance personnel of the maintenance center 8 determines coordinates of the at least one area to be adjusted in the first image information based on the first image information transmitted to the server 9 by the user. In addition, the user also transmits information such as a model number and operating system specifications of the mobile device 1 to the server 9, and the maintenance personnel of the maintenance center 8 can obtain the size, resolution, drivers and the coordinates of the display module 11 based on the model number of the mobile device 1. After determining the coordinates of the area to be adjusted in the first image information, the maintenance personnel will provide a display module adjustment scheme based on the area to be adjusted. In other words, the maintenance personnel of the maintenance center will provide a display module adjustment scheme based on the coordinates of the display module 11 of the mobile device 1, a location of the at least one area to be adjusted, and the content to be adjusted of the first image information.

After the display module adjustment scheme is determined, the maintenance personnel can upload the display module adjustment scheme to the server 9, and the user can then access the display module adjustment scheme from the server 9. In addition, the server 9 can directly provide the display module adjustment scheme to the user's mobile device 1, but it is not limited in the present disclosure. In the embodiment, the display module adjustment scheme is a firmware or an adjustment parameter, but it is not limited in the present disclosure.

In step S140 and step S150, after receiving the display module adjustment scheme, the user can adjust the display module 11 of the mobile device 1 based on the display module adjustment scheme. After the display module 11 of the mobile device 1 is adjusted based on the display module adjustment scheme, the user needs to capture a second image information of the display module 11 and transmit the second image information to the server 9. The maintenance personnel of the maintenance center 8 can confirm an adjustment result based on the second image information uploaded by the user. If the previous issues of the first image information have been solved, the adjustment procedure can be ended. If the previous issues are still not solved, steps S110 to S150 must be repeated until the issues are solved.

### Second Embodiment

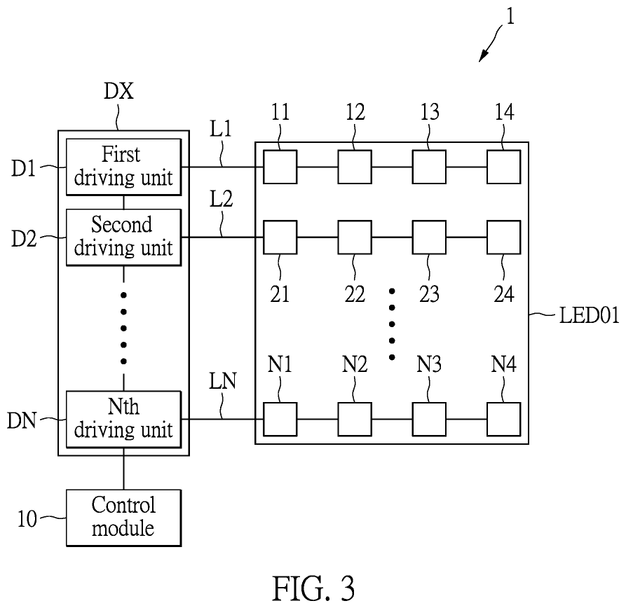

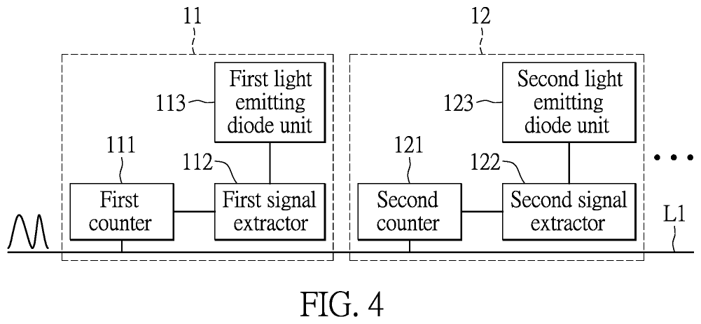

Referring to FIG. 3 and FIG. 4, FIG. 3 is a schematic diagram of a light-emitting diode array driving system of a second embodiment of the present disclosure. FIG. 4 is a schematic diagram of a light-emitting diode module of the second embodiment of the present disclosure.

The light-emitting diode array driving system 1 of this embodiment includes a control module 10, a driving module DX, and a light-emitting diode array LED01. The driving module DX includes a plurality of driving units D1 to DN. The plurality of driving units D1 to DN are electrically connected to a plurality of signal driving lines L1 to LN, respectively. The light-emitting diode array LED01 includes a plurality of light-emitting diode modules 11-14, 21-24, and N1-N4. In the embodiment, the quantity of light-emitting diode modules is not limited. The control module 10 is electrically connected to the driving module DX, and provides a control signal having address information to the driving module. The control signal will include the address information of the row (address information of the driving unit) and a sequence of the light-emitting diode module.

The plurality of light-emitting diode modules 11-14, 21-24, and N1-N4 are arranged in a matrix. The plurality of light-emitting diode modules in the same row are electrically connected to one of the plurality of signal driving lines L1 to LN. In other words, the plurality of light-emitting diode modules 11 to 14 arranged in the same row are electrically connected to a first signal driving line L1. The plurality of light-emitting diode modules 21 to 24 arranged in the same row are electrically connected to a second signal driving line L2. The plurality of light-emitting diode modules N1 to N4 arranged in the same row are electrically connected to an Nth signal driving line LN.

The plurality of driving units D1 to DN of the driving module DX respectively provide a driving signal to the plurality of signal driving lines L1 to LN. In other words, each of the driving unit provides the driving signal to the signal driving lines L1 to LN connected thereto. The signal driving lines L 1-LN transmit the driving signals to the plurality of light-emitting diode modules 11-14, 21-24, and N1-N4.

Furthermore, each of the plurality of light-emitting diode modules 11-14, 21-24, and N1-N4 connected to the same signal driving line respectively extracts, based on a sequence, at least one driving unit signal in the driving signal to emit light.

Although the plurality of light-emitting diode modules 11-14, 21-24, and N1-N4 of the light-emitting diode array LED01 in this embodiment are arranged in a matrix, the display module 11 lacks signal lines and scan lines that are commonly used. The signal line and scan line of the display module 11 are combined into one line. Moreover, the plurality of light-emitting diode modules 11-14, 21-24, and N1-N4 in the same row are electrically connected to the same signal driving line. The light-emitting diode modules 11-14, 21-24, and N1-N4 arranged in one row are not electrically connected to the light-emitting diode modules 11-14, 21-24, and N1-N4 arranged in another row.

Referring to FIG. 4, the first light-emitting diode module 11 and the second light-emitting diode module 12 connected to the first signal driving line L 1 are taken as an example.

The first light-emitting diode module 11 includes a first counter 111, a first signal extractor 112, and a first light-emitting diode unit 113.

The first counter 111 is electrically connected to the first signal driving line L1. The first signal extractor 112 is electrically connected to the first counter 111. The first light-emitting diode unit 113 is electrically connected to the first signal extractor 112. The first signal extractor 112 includes a filter circuit and an amplifying circuit.

The second light-emitting diode module 12 includes a second counter 121, a second signal extractor 122, and a second light-emitting diode unit 123.

The second counter 121 is electrically connected to the first signal driving line L1. The second signal extractor 122 is electrically connected to the second counter 121. The second light-emitting diode unit 123 is electrically connected to the second signal extractor 122. The second signal extractor 122 includes a filter circuit and an amplifying circuit.

Both of the first counter 111 and the second counter 121 are used to count a quantity of signals of the driving signals. The first signal extractor 112 and the second signal extractor 122 are respectively configured to extract a first driving unit signal S1 corresponding to a sequence of the first light-emitting diode 113 or a second driving unit signal S2 corresponding to a sequence of the second light-emitting diode unit 123. After the first signal extractor 112 and the second signal extractor 122 respectively extract the first driving unit signal S1 and the second driving unit signal S2, the first driving unit signal S1 and the second driving unit signal S2 are respectively provided to the first light-emitting diode unit 113 and the second light-emitting diode unit 123 such that the first light-emitting diode unit 113 and the second light-emitting diode unit 123 are drove to emit light.

The sequence of the light-emitting diode modules are firstly counted from a light-emitting diode module adjacent to the driving unit. The light-emitting diode module adjacent to the driving unit is a first light-emitting diode module, the light-emitting diode module adjacent to the first light-emitting diode module is a second light-emitting diode module, and the light-emitting diode module adjacent to the second light-emitting diode module is a third light-emitting diode module.

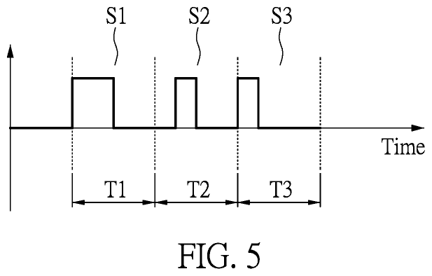

Referring to FIG. 5, the first light-emitting diode unit 113 and the second light-emitting diode unit 123 receive the first driving unit signal S1 and the second driving unit signal S2 from the signal driving line L 1. In other words, when the quantity of light-emitting diode modules electrically connected to the signal driving line L1 is a first quantity, the corresponding driving unit provides the first quantity of driving unit signals to the signal driving line L 1 within a unit time interval. The first quantity is a natural number, and the first quantity is greater than or equal to 1. The second driving unit signal S2 of a second time interval T2 and a third driving unit signal S3 of a third time interval T3 are signals for driving the second light-emitting diode unit 123 and the third diode unit (not shown in figures), respectively.

In FIG. 5, a frame time of each of the driving unit signals S1-S3 is equal to the first time interval T1. In other words, the first time interval T1 is equal to the second time interval T2 and the third time interval T3. In addition, since there are four light-emitting diode modules arranged in each column of the light-emitting diode array LED01, the driving unit provides four driving unit signals every unit time. In other words, each unit time is quadruple of the first time interval T1. The quantity of light-emitting diode modules can be adjusted based on actual requirements, and the unit time of providing driving signal of the driving unit is also adjusted based on the quantity of light-emitting diode modules.

The light-emitting diode array driving system 1 of this embodiment is capable of being applied to the adjustment method of the previous embodiment, and being applied to a light-emitting diode display device or other backlight modules.

For example, the light-emitting diode array driving system 1 in this embodiment is arranged in a backlight module of a direct LED liquid crystal display device. The coordinate of the light-emitting diode array driving system 1 in this embodiment can take the driving unit as a first parameter of the coordinate system, and the light-emitting diode module is taken as a second parameter of the coordinate system. In other words, the first light-emitting diode module 11 of the embodiment is connected to the first driving unit D 1. The maintenance personnel can take the driving unit as the first parameter (can be vertical or horizontal) of the coordinate system, and then take the light-emitting diode module as the second parameter (can be vertical or horizontal) of the coordinate system to make an accurate location description.

In conclusion, the display module adjustment method provided in the present disclosure can effectively reduce the time and cost spent on mailing or bringing over the mobile device for maintenance. Furthermore, the light-emitting diode array driving system provided by the present disclosure can simplify the circuit structure and reduce the installation cost and maintenance cost.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A light-emitting diode array driving system, comprising:
a driving module including a plurality of driving units, the plurality of driving units being electrically connected to a plurality of signal driving lines; and
a light-emitting diode array including a plurality of light-emitting diode modules, the plurality of light-emitting diode modules being arranged in a matrix, the light-emitting diode modules arranged in the same row or the light-emitting diode modules arranged in the same column being electrically connected to one of the plurality of signal driving lines;
wherein the driving units of the driving module respectively provide a driving signal to the plurality of signal driving lines, the light-emitting diode modules connected to the same signal driving line respectively extracts, based on a sequence, at least one driving unit signal of the driving signal to drive the light-emitting diode module.

2. The light-emitting diode array driving system according to claim 1, wherein each of the light-emitting diode modules includes:
a counter counting a quantity of the driving signals;
a signal extractor being electrically connected to the counter to extract the driving unit signal of the light-emitting diode module based on the sequence; and
a light-emitting diode unit being electrically connected to the signal extractor to receive the driving unit signal for emitting light.

3. The light-emitting diode array driving system according to claim 1, wherein the light-emitting diode modules connected to one of the signal driving lines are not electrically connected to the light-emitting diode modules connected to another one of the signals driving lines.

4. The light-emitting diode array driving system according to claim 1, wherein when a quantity of the light-emitting diode modules connected to one of plurality of the signal driving lines is a first quantity, the driving unit connected to the one of the plurality of signal driving lines provides the driving unit signals having the first quantity to the signal driving lines in a unit time interval.

5. The light-emitting diode array driving system according to claim 1, further comprising a control module, the control module being electrically connected to the driving module to provide a control signal having an address information to the driving module.

6. A display module adjustment method of a mobile device, comprising:
capturing a first image information of a display module of the mobile device;
transmitting the first image information to a server;
providing a display module adjustment scheme to the mobile device based on at least one area to be adjusted of the first image information;
adjusting the display module based on the display module adjustment scheme, capturing a second image information, and transmitting the second image information to the sever; and
confirming an adjustment result based on the second image information.

7. The display module adjustment method according to claim 6, wherein the display module is a liquid crystal display module, an organic light-emitting diode display module, or a light-emitting diode display module.

8. The display module adjustment method according to claim 6, wherein the display module adjustment scheme is a firmware or adjustment parameters.

9. The display module adjustment method according to claim 6, wherein the first information is a black screen image information or a blank screen image information.

10. The display module adjustment method according to claim 6, wherein the display adjustment scheme based on a coordinate of the display module of the mobile device, a location of the at least one area to be adjusted, and a content to be adjusted.
